(19) United States
(12) Patent Application Publication
(10) Pub. No.: US 2014/0061670 A1
(43) Pub. Date: Mar. 6, 2014

(54) WIDE GAP SEMICONDUCTOR DEVICE AND METHOD FOR MANUFACTURING THE SAME

(71) Applicant: Sumitomo Electric Industries, Ltd., Osaka-shi (JP)

(72) Inventors: Keiji Wada, Osaka-shi (JP); Kenji Kanbara, Osaka-shi (JP)

(73) Assignee: Sumitomo Electric Industries, Ltd., Osaka-shi (JP)

(21) Appl. No.: 13/947,765

(22) Filed: Jul. 22, 2013

Related U.S. Application Data
(60) Provisional application No. 61/697,672, filed on Sep. 6, 2012.

(30) Foreign Application Priority Data
Sep. 6, 2012 (JP) 2012-195798

(51) Int. Cl. H01L 29/872; H01L 29/66

(52) U.S. Cl. CPC H01L 29/872; H01L 29/66143
USPC 257/77; 438/572

(57) ABSTRACT

A wide gap semiconductor device has a substrate and a Schottky electrode. The substrate is made of a wide gap semiconductor material and has a first conductivity type. The Schottky electrode is arranged on the substrate to be in contact therewith and is made of a single material. The Schottky electrode includes a first region having a first barrier height and a second region having a second barrier height higher than the first barrier height. The second region includes an outer peripheral portion of the Schottky electrode. Thus, a wide gap semiconductor device capable of achieving less leakage current and a method for manufacturing the same can be provided.

### BACKGROUND OF THE INVENTION

1. Field of the Invention

The present invention relates to a wide gap semiconductor device and a method for manufacturing the same and more particularly to a wide gap semiconductor device capable of achieving a suppressed leakage current and a method for manufacturing the same.

2. Description of the Background Art

Such a semiconductor device as a Schottky barrier diode (SBD) or a junction barrier Schottky diode (JBS) has a structure that a Schottky electrode is formed on a substrate. Since a Schottky barrier diode is small in difference in work function between a metal and a semiconductor employed as electrode materials, a leakage current at the time of application of a reverse voltage tends to be higher than in a PN diode. Therefore, various structures for lowering a leakage current have been proposed.

For example, Japanese Patent Laying-Open No. 2001-85704 discloses a silicon carbide Schottky diode in which a p⁺ guard ring region is formed in a substrate portion in contact with a peripheral portion of a Schottky electrode and a pn junction is formed to be in contact with a main surface of a substrate. In addition, Japanese Patent Laying-Open No. 2009-16603 discloses a junction barrier Schottky diode in which a plurality of p-type layers provided in a substrate in contact with a Schottky diode are concentrically provided.

### SUMMARY OF THE INVENTION

It has been difficult, however, to sufficiently lower a leakage current in the Schottky diodes described in Japanese Patent Laying-Open No. 2001-85704 and Japanese Patent Laying-Open No. 2009-16603.

The present invention was made in view of the problems above, and an object thereof is to provide a wide gap semiconductor device capable of achieving less leakage current and a method for manufacturing the same.

A wide gap semiconductor device according to the present invention mainly includes a substrate and a Schottky electrode. The substrate is made of a wide gap semiconductor material and has a first conductivity type. The Schottky electrode is arranged on the substrate to be in contact therewith and is made of a single material. The Schottky electrode includes a first region having a first barrier height and a second region having a second barrier height higher than the first barrier height. The second region includes an outer peripheral portion of the Schottky electrode. It is noted that the wide gap semiconductor material refers to a semiconductor material greater in band gap than silicon.

According to the wide gap semiconductor device of the present invention, the second region having the second barrier height higher than the first barrier height includes the outer peripheral portion of the Schottky electrode. By providing the outer peripheral portion of the Schottky electrode where electric field tends to be concentrated in the second region having a high barrier height, a leakage current caused by the electric field applied to a Schottky interface can efficiently be lowered.

In the wide gap semiconductor device according to the above, preferably, the wide gap semiconductor material is silicon carbide. Thus, a wide gap semiconductor device having a high breakdown voltage is obtained.

In the wide gap semiconductor device according to the above, preferably, a width of the second region in a direction in parallel to a main surface of the substrate and from the outer peripheral portion of the Schottky electrode toward a center is not smaller than 2 μm and not greater than 100 μm.

In the wide gap semiconductor device according to the above, preferably, the substrate includes a second conductivity type region in contact with the outer peripheral portion of the Schottky electrode. Thus, electric field in the outer peripheral portion of the Schottky electrode can be relaxed.

A method for manufacturing a wide gap semiconductor device according to the present invention includes the following steps. A substrate made of a wide gap semiconductor material and having a first conductivity type is prepared. A Schottky electrode in contact with the substrate, which is made of a single material, is formed. In the step of forming a Schottky electrode, an outer peripheral portion of the Schottky electrode is locally heated.

The method for manufacturing a wide gap semiconductor device according to the present invention has the step of locally heating the outer peripheral portion of the Schottky electrode. By locally heating the outer peripheral portion of the Schottky electrode, a barrier height of the outer peripheral portion of the Schottky electrode where electric field tends to be concentrated can be increased. Thus, a leakage current caused by the electric field applied to a Schottky interface can efficiently be lowered.

In the method for manufacturing a wide gap semiconductor device according to the above, preferably, the step of locally heating an outer peripheral portion of the Schottky electrode is performed through laser annealing. Thus, the outer peripheral portion of the Schottky electrode can locally be heated with high accuracy.

In the method for manufacturing a wide gap semiconductor device according to the above, preferably, the step of forming a Schottky electrode includes the step of heating the entire Schottky electrode before the step of locally heating the outer peripheral portion of the Schottky electrode. Thus, a barrier height of the Schottky electrode can be adjusted to an appropriate value.

In the method for manufacturing a wide gap semiconductor device according to the above, preferably, the step of heating the entire Schottky electrode is performed through laser annealing. Thus, the Schottky electrode can efficiently be heated.

According to the present invention, a wide gap semiconductor device capable of achieving less leakage current and a method for manufacturing the same can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view schematically showing a structure of a wide gap semiconductor device according to one embodiment of the present invention.

FIG. 2 is a schematic plan view schematically showing positional relation between a Schottky electrode and a second conductivity type region of the wide gap semiconductor device according to one embodiment of the present invention.

FIG. 3 is a flowchart schematically showing a method for manufacturing a wide gap semiconductor device according to one embodiment of the present invention.

FIG. 4 is a flowchart schematically showing the method for manufacturing a wide gap semiconductor device according to one embodiment of the present invention.

FIG. 5 is a schematic cross-sectional view schematically showing a first step in the method for manufacturing a wide gap semiconductor device according to one embodiment of the present invention.

FIG. 6 is a schematic cross-sectional view schematically showing a second step in the method for manufacturing a wide gap semiconductor device according to one embodiment of the present invention.

FIG. 7 is a schematic cross-sectional view schematically showing a third step in the method for manufacturing a wide gap semiconductor device according to one embodiment of the present invention.

FIG. 8 is a schematic cross-sectional view schematically showing a fourth step in the method for manufacturing a wide gap semiconductor device according to one embodiment of the present invention.

FIG. 9 is a schematic cross-sectional view schematically showing a construction of a Schottky barrier diode for measuring a barrier height.

FIG. 10 is a diagram showing relation between current density and a voltage.

FIG. 11 is a diagram showing relation between a barrier height and an annealing temperature.

### DESCRIPTION OF THE PREFERRED EMBODIMENTS

An embodiment of the present invention will be described hereinafter with reference to the drawings. It is noted that the same or corresponding elements in the drawings below have the same reference characters allotted and description thereof will not be repeated.

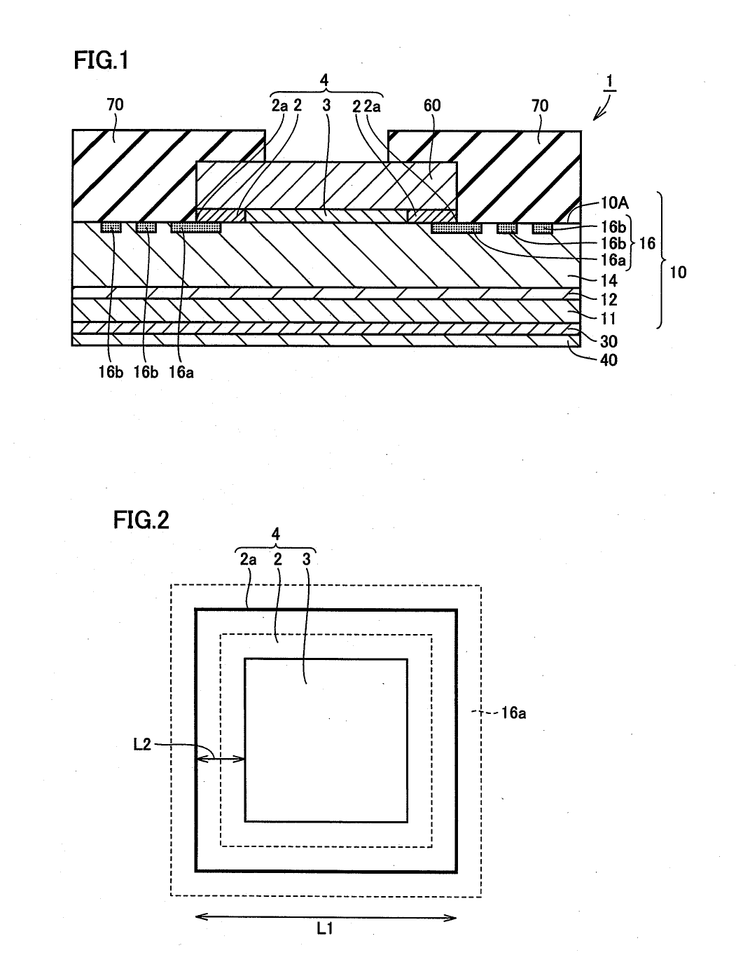

A structure of a Schottky barrier diode 1 representing a wide gap semiconductor device according to one embodiment of the present invention will initially be described with reference to FIG. 1. As shown in FIG. 1, Schottky barrier diode 1 in the present embodiment mainly has a substrate 10, a Schottky electrode 4, and an ohmic electrode 30. Substrate 10 is made of a wide gap semiconductor material and has an n-type (a first conductivity type). The wide gap semiconductor material refers to a semiconductor material greater in band gap than silicon, and silicon carbide, gallium nitride, diamond, and the like are specifically exemplified.

Substrate 10 has an n⁺ substrate 11, an electric field stop layer 12, an n-type region 14, and a JTE (Junction Termination Extension) region 16. N⁺ substrate 11 is a substrate composed of single crystal silicon carbide and containing such an impurity as nitrogen (N). A concentration of an impurity contained in the n⁺ substrate is, for example, around 5×10¹⁸ cm⁻³. A concentration of such an impurity as nitrogen contained in electric field stop layer 12 is, for example, not lower than around 5×10¹⁷ cm⁻³ and not higher than around 1×10¹⁸ cm⁻³.

JTE region 16 is a p-type region into which ions of such an impurity as aluminum (Al) or boron (B) have been implanted. A concentration of an impurity in the p-type region is, for example, around 2×10¹⁷ cm⁻³. JTE region 16 includes a p-type region 16a in contact with an outer peripheral portion 2a of Schottky electrode 4 and a p-type region 16b arranged on an outer peripheral side of p-type region 16a and not being in contact with Schottky electrode 4. In addition, substrate 10 may have a field stop region (not shown) so as to surround JTE region 16. The field stop region is, for example, an n⁺ type region into which ions of phosphorus (P) or the like have been implanted.

Schottky electrode 4 is provided on one main surface 10A of substrate 10, and it is composed, for example, of titanium (Ti). For Schottky electrode 4, other than titanium, for example, nickel (Ni), titanium nitride (TiN), gold (Au), molybdenum (Mo), tungsten (W), and the like may be employed. Schottky electrode 4 is made of a single material. The single material includes a case of a simple substance composed of the same element and a case of the same compound. In addition, even in a case where the material is formed, for example, with sputtering or plating and thereafter a part of the material is heated to thereby change a state of bonding in the part of the material, a portion where the state of bonding changed and a portion where the state of bonding remained unchanged are of a single material.

Schottky electrode 4 includes a first region 3 having a first barrier height and a second region 2 having a second barrier height higher than the first barrier height. Second region 2 includes outer peripheral portion 2a of Schottky electrode 4. Second region 2 may include the entire outer peripheral portion 2a of Schottky electrode 4 or may include a part of outer peripheral portion 2a. Preferably, second region 2 includes the entire outer peripheral portion 2a of Schottky electrode 4.

Referring to FIG. 2, when viewed in a direction of a normal of substrate 10, first region 3 is surrounded by second region 2. A shape of Schottky electrode 4 is, for example, square when viewed in the direction of the normal of substrate 10. One side L1 of Schottky electrode 4 has a length, for example, of 1 mm. One side L1 of Schottky electrode 4 may have a length, for example, of 5 mm or 7 mm. Preferably, a width L2 of second region 2 in a direction in parallel to main surface 10A of substrate 10 and from outer peripheral portion 2a of Schottky electrode 4 toward a center is not smaller than 2 μm and not greater than 100 μm. Preferably, outer peripheral portion 2a of Schottky electrode 4 is in contact with p-type region 16a.

Referring to FIG. 1, a pad electrode 60 is formed to be in contact with first region 3 and second region 2 of Schottky electrode 4. Pad electrode 60 is made, for example, of aluminum. A protection film 70 is formed to be in contact with pad electrode 60, second region 2, and main surface 10A of substrate 10. In addition, an ohmic electrode 30 is arranged to be in contact with n⁺ substrate 11. Ohmic electrode 30 is made, for example, of nickel. Furthermore, a pad electrode 40 made, for example, of titanium, nickel, silver, or an alloy thereof is arranged to be in contact with ohmic electrode 30.

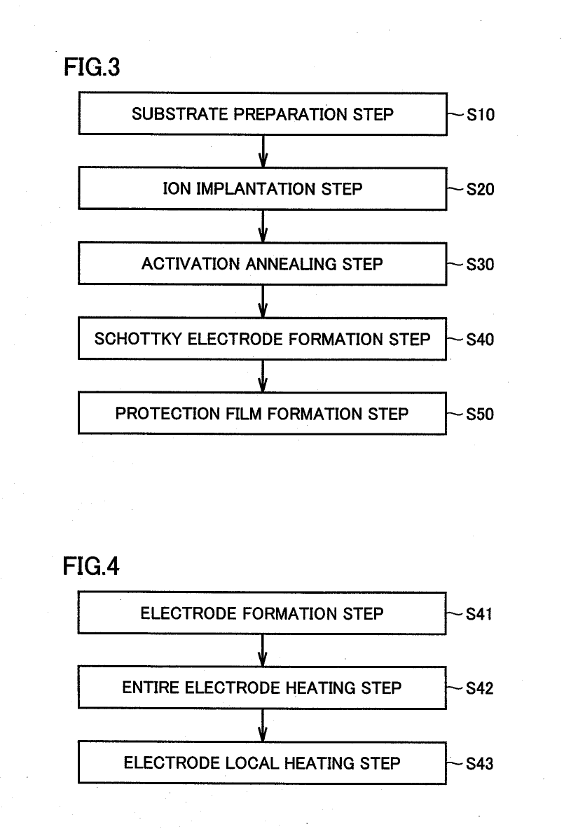

A method for manufacturing a Schottky barrier diode representing the wide gap semiconductor device according to one embodiment of the present invention will now be described with reference to FIGS. 3 to 9.

Referring to FIG. 5, initially, as a step (S10: FIG. 3), a substrate preparation step is performed. In this step (S 10), by slicing an ingot (not shown) made of single crystal silicon carbide having a poly type, for example, of 4H, n⁺ substrate 11 having the n conductivity type (the first conductivity type) is prepared. The n⁺ substrate contains such an impurity as nitrogen (N). A concentration of an impurity contained in the n⁺ substrate is, for example, around 5×10¹⁸ cm⁻³.

Then, electric field stop layer 12 is formed on n⁺ substrate 11. Electric field stop layer 12 is a silicon carbide layer having the n-type. A concentration of such an impurity as nitrogen contained in electric field stop layer 12 is, for example, not lower than around 5×10¹⁷ cm⁻³ and not higher than around 1×10¹⁸ cm⁻³. Thereafter, n-type region 14 having the n conductivity type (the first conductivity type) is formed on electric field stop layer 12 through epitaxial growth. Thus, substrate 10 made of a wide gap semiconductor material and having the first conductivity type is prepared.

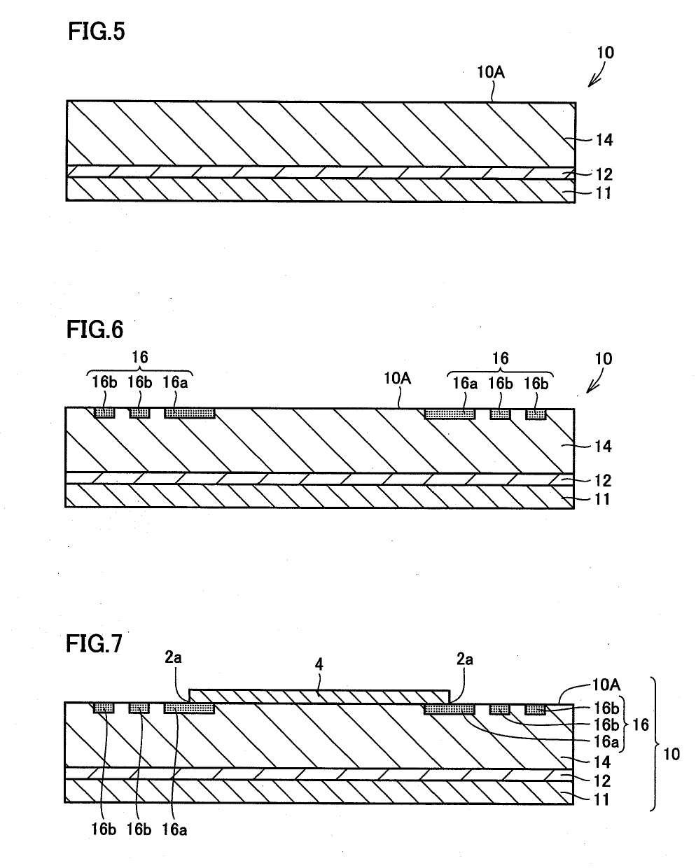

Then, as a step (S20: FIG. 3), an ion implantation step is performed. In this step (S20), referring to FIG. 6, initially, for example, a mask having an opening in a region where JTE region 16 is to be formed and made of silicon dioxide is formed on substrate 10. Thereafter, for example, as Al (aluminum) ions are implanted into n-type region 14, JTE region 16 having a p conductivity type (a second conductivity type) is formed. A concentration of an impurity in JTE region 16 is, for example, around 2×10¹⁷ cm⁻³.

Then, as a step (S30: FIG. 3), an activation annealing step is performed. In this step (S30), substrate 10 is heated in an atmosphere of such an inert gas as argon at a temperature around 1800° C., so that JTE region 16 is annealed and the impurity introduced in the step above (S20) is activated. Thus, desired carries are generated in the region into which the impurity has been introduced.

Then, as a step (S40: FIG. 3), a Schottky electrode formation step is performed. The Schottky electrode formation step preferably includes an electrode formation step (S41: FIG. 4), an entire electrode heating step (S42: FIG. 4), and an electrode local heating step (S43: FIG. 4). Initially, in the electrode formation step (S41), Schottky electrode 4 composed of a single material is formed to be in contact with substrate 10. Schottky electrode 4 is a film of such a metal as titanium (Ti), nickel (Ni), molybdenum (Mo), tungsten (W), or titanium nitride (TiN). Specifically, referring to FIG. 7, Schottky electrode 4 is formed to be in contact with n-type region 14 at main surface 10A of substrate 10 and to be in contact with p-type region 16a at main surface 10A of substrate 10. In addition, outer peripheral portion 2a of the Schottky electrode is formed to be in contact with p-type region 16a at main surface 10A of substrate 10.

Then, the entire electrode heating step (S42) is performed. In this step (S42), the entire Schottky electrode 4 formed on main surface 10A of substrate 10 is heated. The entire Schottky electrode 4 is heated, for example, through laser annealing. Substrate 10 having Schottky electrode 4 formed may be arranged in a heating furnace and the entire Schottky electrode 4 may be heated in an inert gas atmosphere. Schottky electrode 4 is heated, for example, up to around 300° C.

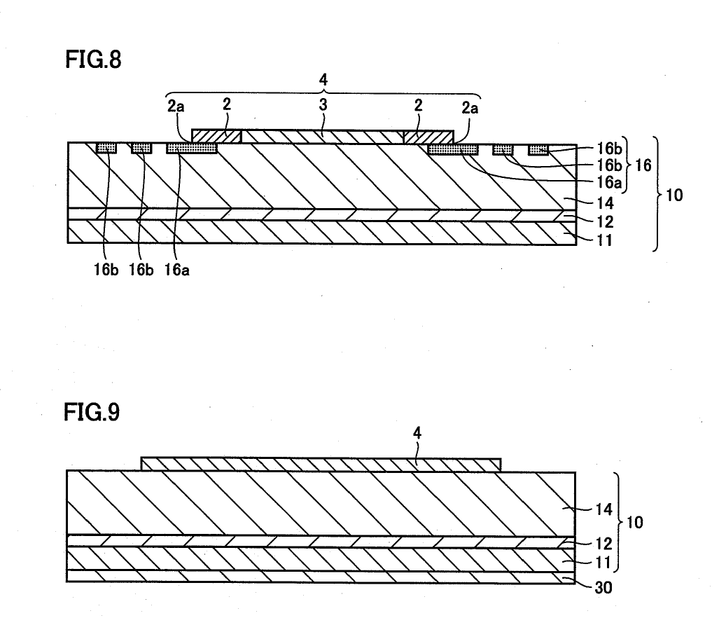

Then, the electrode local heating step (S43) is performed. In this step (S43), referring to FIG. 8, outer peripheral portion 2a of Schottky electrode 4 and second region 2 including outer peripheral portion 2a are locally heated. Outer peripheral portion 2a of Schottky electrode 4 and second region 2 including outer peripheral portion 2a are preferably heated through laser annealing. Outer peripheral portion 2a of Schottky electrode 4 and second region 2 including outer peripheral portion 2a may be heated with the use of electron beams. In addition, outer peripheral portion 2a of Schottky electrode 4 is heated to a temperature, for example, not lower than around 450° C. and not higher than around 550° C. A temperature for heating Schottky electrode 4 in the electrode local heating step (S43) is higher than a temperature for heating Schottky electrode 4 in the entire electrode heating step (S42). The entire outer peripheral portion 2a of Schottky electrode 4 may locally be heated, or a part of outer peripheral portion 2a may locally be heated. Preferably, the electrode local heating step (S43) is performed after the entire electrode heating step (S42).

By heating second region 2 including outer peripheral portion 2a of Schottky electrode 4 through the electrode local heating step (S43), a barrier height of second region 2 becomes higher than a barrier height of first region 3 of Schottky electrode 4 which is not locally heated. In other words, through the electrode local heating step (S43), Schottky electrode 4 including first region 3 having a first barrier height and second region 2 having a second barrier height higher than the first barrier height is formed. The first barrier height of first region 3 is, for example, around 0.85 eV, and the second barrier height of second region 2 is, for example, around 1.15 eV. The second barrier height of second region 2 is higher than the first barrier height of first region 3 by 0.1 eV or more and preferably by 0.20 eV or more.

For example, YAG laser is employed for laser annealing, and more specifically, solid-state laser of YVO₄ having a wavelength of 355 nm (a third harmonic) is employed. A laser emission beam spot has a diameter, for example, not smaller than 200 μm and not greater than 300 μm. An area of an emission beam spot at the surface of Schottky electrode 4 is preferably not smaller than 0.03 mm². An emission beam spot moves so as to overlap with a previous emission beam spot. For example, in a case where scanning with pulse laser at 20 kHz is carried out at 1000 mm per second, a scanning pitch between emission beam spots is set to 50 p.m. The emission beam spots scan Schottky electrode 4 in a certain direction (a scanning direction) while overlapping with each other.

Then, a pad electrode and protection film formation step is performed. Specifically, pad electrode 60 made, for example, of aluminum is formed on Schottky electrode 4 to be in contact therewith. Thereafter, protection film 70 is formed to be in contact with pad electrode 60, second region 2 of Schottky electrode 4, and main surface 10A of substrate 10.

Then, an ohmic electrode formation step is performed. Specifically, a surface opposite to main surface 10A of substrate 10 (a back surface) is ground and ohmic electrode 30 made, for example, of nickel is formed to be in contact with the back surface. Thereafter, pad electrode 40 made, for example, of titanium, nickel, silver, or an alloy thereof is formed to be in contact with ohmic electrode 30.

Then, as a step (S50: FIG. 3), a passivation protection film formation step is performed. Specifically, for example with plasma CVD, a passivation protection film 70 in contact with pad electrode 60, second region 2, and main surface 10a of silicon carbide substrate 10 is formed. Passivation protection film 70 is formed from a film, for example, of silicon dioxide (SiO₂) or silicon nitride (SiN), or a stack film thereof. Thus, Schottky barrier diode 1 representing a wide gap semiconductor device shown in FIG. 1 is completed.

Though description of the present embodiment has been given with the n-type being defined as the first conductivity type and the p-type being defined as the second conductivity type, the p-type may be defined as the first conductivity type and the n-type may be defined as the second conductivity type. In addition, though a Schottky barrier diode has been described in the present embodiment by way of example of a wide gap semiconductor device, the present invention is not limited thereto. A wide gap semiconductor device should only be a transistor having a Schottky junction, and it may be, for example, a MESFET (Metal Semiconductor Field Effect Transistor), a HEMT (High Electron Mobility Transistor), or the like.

Functions and effects of Schottky barrier diode 1 and the method for manufacturing the same according to an embodiment will now be described.

According to Schottky barrier diode 1 in the present embodiment, outer peripheral portion 2a of Schottky electrode 4 includes second region 2 having a second barrier height higher than a first barrier height. By providing outer peripheral portion 2a of Schottky electrode 4 where electric field tends to be concentrated in second region 2 having a high barrier height, a leakage current caused by electric field applied to a Schottky interface can efficiently be lowered.

In addition, Schottky barrier diode 1 according to the present embodiment is composed of silicon carbide. Thus, Schottky barrier diode 1 having a high breakdown voltage is obtained.

Furthermore, according to Schottky barrier diode 1 in the present embodiment, a width of second region 2 in a direction in parallel to main surface 10A of substrate 10 and from outer peripheral portion 2a of Schottky electrode 4 toward the center is not smaller than 2 μm and not greater than 100 μm.

Moreover, according to Schottky barrier diode 1 in the present embodiment, substrate 10 includes p-type region 16a (the second conductivity type region) in contact with outer peripheral portion 2a of Schottky electrode 4. Thus, electric field in outer peripheral portion 2a of Schottky electrode 4 can be relaxed.

The method for manufacturing Schottky barrier diode 1 according to the present embodiment has the step of locally heating outer peripheral portion 2a of Schottky electrode 4. By locally heating outer peripheral portion 2a of Schottky electrode 4, a barrier height of outer peripheral portion 2a of Schottky electrode 4 where electric field tends to be concentrated can be increased. Thus, a leakage current caused by electric field applied to the Schottky interface can efficiently be lowered.

In addition, according to the method for manufacturing Schottky barrier diode 1 in the present embodiment, the step of locally heating outer peripheral portion 2a of Schottky electrode 4 is performed through laser annealing. Thus, outer peripheral portion 2a of Schottky electrode 4 can locally be heated with high accuracy.

Furthermore, according to the method for manufacturing Schottky barrier diode 1 in the present embodiment, the step of forming Schottky electrode 4 includes the step of heating the entire Schottky electrode 4 before the step of locally heating outer peripheral portion 2a of Schottky electrode 4. Thus, a barrier height of Schottky electrode 4 can be adjusted to an appropriate value.

Moreover, according to the method for manufacturing Schottky barrier diode 1 in the present embodiment, the step of heating the entire Schottky electrode 4 is performed through laser annealing. Thus, Schottky electrode 4 can efficiently be heated.

### Example

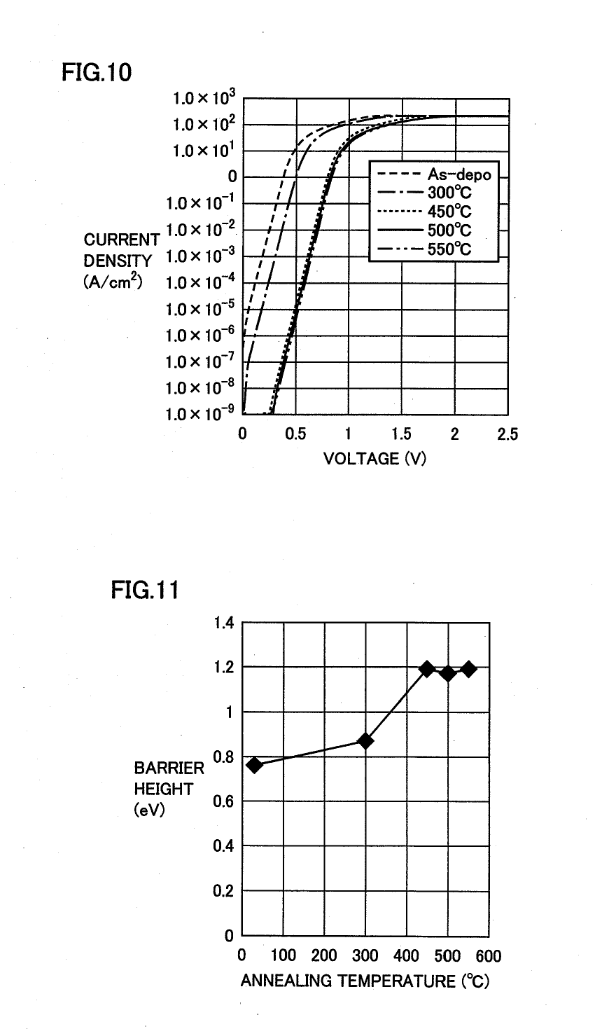

In the present example, relation between a temperature for annealing a Schottky electrode and a barrier height of a Schottky barrier diode has been investigated. Initially, a Schottky barrier diode as shown in FIG. 9 was manufactured with a method the same as the method described in the first embodiment. Specifically, Schottky electrode 4 was made of titanium. Electric field stop layer 12 was formed on n′ substrate 11 and an n⁻ drift layer was formed on electric field stop layer 12. Ohmic electrode 30 was formed on a side of n⁺ substrate 11 opposite to electric field stop layer 12. Schottky electrode 4 was heated through laser annealing. A temperature for laser annealing was set to room temperature (As-depo), 300° C., 450° C., 500° C., and 550° C. A time period for annealing was set to 5 minutes in all temperature conditions. As shown in FIG. 10, current density was measured while a voltage for 5 types of Schottky barrier diodes different in annealing temperature was varied from 0 V to 2.5 V. A barrier height (φ_{b}) was calculated by using the equation below. It is noted that J₀ represents current density when a voltage was set to 0 V, k represents a Boltzmann constant, A* represents a Richardson constant, e represents a unit charge, and T represents a temperature.

$${φ}_{b} = - \frac{kT}{e} \cdot log ( \frac{{J}_{0}}{{A}^{*} {T}^{2}} )$$

Relation between a barrier height and an annealing temperature will be described with reference to FIG. 11. As shown in FIG. 11, when an annealing temperature is higher in a region where an annealing temperature is not higher than 450° C., a barrier height tends to be higher. In a case where an annealing temperature is set to a room temperature (that is, without annealing being performed), a barrier height was around 0.75 eV, and in a case where an annealing temperature was set to 300° C., a barrier height was around 0.85 eV. When an annealing temperature was from around 450° C. to around 550° C., a barrier height was around 1.20 eV. From the foregoing, it was confirmed that, by locally heating second region 2 including outer peripheral portion 2a of Schottky electrode 4, a barrier height of second region 2 can be higher than a barrier height of first region 3 which was not locally heated.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A wide gap semiconductor device, comprising:
a substrate made of a wide gap semiconductor material and having a first conductivity type; and
a Schottky electrode arranged on said substrate to be in contact therewith and made of a single material,
said Schottky electrode including a first region having a first barrier height and a second region having a second barrier height higher than said first barrier height, and
said second region including an outer peripheral portion of said Schottky electrode.

2. The wide gap semiconductor device according to claim 1, wherein
said wide gap semiconductor material is silicon carbide.

3. The wide gap semiconductor device according to claim 1, wherein
a width of said second region in a direction in parallel to a main surface of said substrate and from said outer peripheral portion of said Schottky electrode toward a center is not smaller than 2 μm and not greater than 100 μm.

4. The wide gap semiconductor device according to claim 1, wherein
said substrate includes a second conductivity type region in contact with said outer peripheral portion of said Schottky electrode.

5. A method for manufacturing a wide gap semiconductor device, comprising the steps of:
preparing a substrate made of a wide gap semiconductor material and having a first conductivity type; and
forming a Schottky electrode in contact with said substrate, which is made of a single material,
said step of forming a Schottky electrode including the step of locally heating an outer peripheral portion of said Schottky electrode.

6. The method for manufacturing a wide gap semiconductor device according to claim 5, wherein
said step of locally heating an outer peripheral portion of said Schottky electrode is performed through laser annealing.

7. The method for manufacturing a wide gap semiconductor device according to claim 5, wherein
said step of forming a Schottky electrode includes the step of heating entire said Schottky electrode before the step of locally heating the outer peripheral portion of said Schottky electrode.

8. The method for manufacturing a wide gap semiconductor device according to claim 7, wherein
said step of heating entire said Schottky electrode is performed through laser annealing.
